(19) United States
(12) Patent Application Publication
(10) Pub. No.: US 2025/0224794 A1
(43) Pub. Date: Jul. 10, 2025

(54) RECORDING MEDIUM AND HOST DEVICE

(71) Applicant: Panasonic Intellectual Property Management Co., Ltd., Osaka (JP)

(72) Inventors: Yoshihisa INAGAKI, Hyogo (JP); Tadashi ONO, Osaka (JP); Isao KATO, Osaka (JP)

(21) Appl. No.: 19/092,046

(22) Filed: Mar. 27, 2025

Related U.S. Application Data
(63) Continuation of application No. PCT/JP2023/031731, filed on Aug. 31, 2023.

(30) Foreign Application Priority Data
Sep. 28, 2022 (JP) 2022-155172

(51) Int. Cl. G06F 1/324; G06F 1/3225

(52) U.S. Cl. CPC G06F 1/324; G06F 1/3225

(57) ABSTRACT

A recording medium in the present disclosure is a recording medium connected to a host device, and includes a memory, a control unit that controls the memory, and an interface unit that communicates with the host device. The interface unit transmits setting information including a rising temperature which is a temperature difference between a surface and an inside of the recording medium, and receives a threshold temperature of thermal throttling from the host device, and the control unit controls an operation based on the threshold temperature.

### BACKGROUND

### 1. Technical Field

The present disclosure relates to a recording device that accesses a recording medium, control of the recording medium, and the recording medium.

### 2. Description of the Related Art

Patent Literature (PTL) 1 discloses a recording device capable of setting a temperature at which a function of a recording medium is restricted. The recording device includes a control unit that sets a temperature threshold at which the function restriction is performed to a value within a range that can be set in the recording medium, and the control unit switches whether to perform a first setting of setting the temperature threshold at which the function restriction is performed in the recording medium to a recording medium default value or a second setting of setting the temperature threshold to a value larger than the default value depending on whether the mode is a reproduction mode or a recording/photographing mode.

As a result, a temperature at which the function of the recording medium is restricted can be set.

PTL 1: Unexamined Japanese Patent Publication No. 2021-87204

### SUMMARY

The present disclosure provides a recording medium and a host device capable of performing threshold setting of thermal throttling in consideration of temperature rise due to heat generation of the recording medium, suppressing thermal throttling, and performing writing and reading at a guaranteed speed.

A recording medium in the present disclosure is a recording medium connected to a host device, the recording medium including: a memory; a control unit that controls the memory; and an interface unit that communicates with the host device, in which the interface unit transmits setting information including a rising temperature that is a temperature difference between a surface and an inside of the recording medium, and receives a threshold temperature of thermal throttling from the host device, and the control unit controls an operation based on the threshold temperature.

A host device in the present disclosure is a host device connected to a recording medium, the host device including a control unit, in which the control unit receives setting information including a rising temperature that is a temperature difference between a surface and an inside of the recording medium, calculates a threshold temperature based on the setting information and a convergence temperature that is a surface temperature of the recording medium that can be controlled when the recording medium is continuously operated at a guaranteed speed, and transmits the threshold temperature calculated to the recording medium.

A recording medium in the present disclosure is a recording medium connected to a host device, the recording medium including: a memory; a control unit that controls the memory; and an interface unit that communicates with the host device, in which the interface unit receives command information including a convergence temperature that is a temperature that can be controlled when the host device is continuously operated, transmits setting information including a threshold temperature calculated by the control unit based on the convergence temperature and a rising temperature that is a temperature difference between a surface and an inside of the recording medium, and receives a threshold temperature of thermal throttling from the host device, and the control unit controls an operation based on the threshold temperature of the thermal throttling.

A host device in the present disclosure is a host device connected to a recording medium, the host device including a control unit, in which the control unit transmits, to the recording medium, command information including a convergence temperature that is a temperature that can be controlled when the recording medium is continuously operated, receives setting information including a threshold temperature calculated by the recording medium based on the convergence temperature and a rising temperature that is a temperature difference between a surface and an inside of the recording medium, and transmits the threshold temperature included in the setting information to the recording medium as a threshold temperature of thermal throttling.

A recording medium in the present disclosure is a recording medium connected to a host device, the recording medium including: a memory; a control unit that controls the memory; and an interface unit that communicates with the host device, in which the interface unit transmits setting information including a relationship between a thermal throttling threshold and a guaranteed speed, and a relationship between a convergence temperature, the guaranteed speed, and an internal temperature of the recording medium, and receives a threshold temperature of thermal throttling from the host device, and the control unit controls an operation based on the threshold temperature.

A host device in the present disclosure is a host device connected to a recording medium, the host device including a control unit, in which the control unit receives setting information including a relationship between a thermal throttling threshold and a guaranteed speed held by the recording medium, and a relationship between a convergence temperature, the guaranteed speed, and an internal temperature of the recording medium, calculates a threshold temperature of thermal throttling and selection information obtained by selecting one of a plurality of thermal throttling thresholds from the relationship between the thermal throttling threshold and the guaranteed speed, and the relationship between the convergence temperature, the guaranteed speed, and the internal temperature of the recording medium, and transmits the selection information and the threshold temperature to the recording medium.

According to the present disclosure, it is possible to perform threshold temperature setting of thermal throttling in consideration of a temperature rise due to heat generation of a recording medium, suppress thermal throttling, and perform writing and reading at a guaranteed speed.

### BRIEF DESCRIPTION OF THE DRAWINGS

FIG. 1 is a schematic diagram illustrating a memory card and a host device according to first and second exemplary embodiments.

FIG. 2 is a sequence diagram inquiring about a rising temperature in the first exemplary embodiment.

FIG. 3 is a sequence diagram inquiring a threshold temperature of thermal throttling in the first exemplary embodiment.

FIG. 4 is a sequence diagram acquiring a correspondence table of the relationship between threshold temperatures TMT1, TMT2 and a guaranteed speed, a card surface temperature, and a relationship between an access speed and a card internal temperature in a second exemplary embodiment.

FIG. 5 is a diagram illustrating a relationship between threshold temperatures TMT1, TMT2 and a guaranteed speed in the second exemplary embodiment.

FIG. 6 is a diagram illustrating a relationship between a card surface temperature, an access speed, and a card internal temperature in the second exemplary embodiment.

FIG. 7 is a flowchart for calculating a threshold on the host side in the first exemplary embodiment.

FIG. 8 is a flowchart for calculating a threshold on the card side in the first exemplary embodiment.

FIG. 9 is a diagram illustrating a temperature change and a threshold during continuous operation of 400 Mbyte/sec in the second exemplary embodiment.

FIG. 10 is a diagram illustrating a temperature change and a threshold during continuous operation of 600 Mbyte/sec in the second exemplary embodiment.

### DETAILED DESCRIPTIONS

Hereinafter, exemplary embodiments will be described in detail with reference to the drawings as appropriate. Note that unnecessarily detailed description is omitted in some cases. For example, a detailed description of an already well-known matter and a duplicated description of substantially the same configuration will be omitted in some cases. This is to avoid unnecessary redundancy of the following description and to facilitate understanding of those skilled in the art.

Note that the accompanying drawings and the following description are provided for those skilled in the art to fully understand the present disclosure, and are not intended to limit the subject matter described in the claims.

### First Exemplary Embodiment

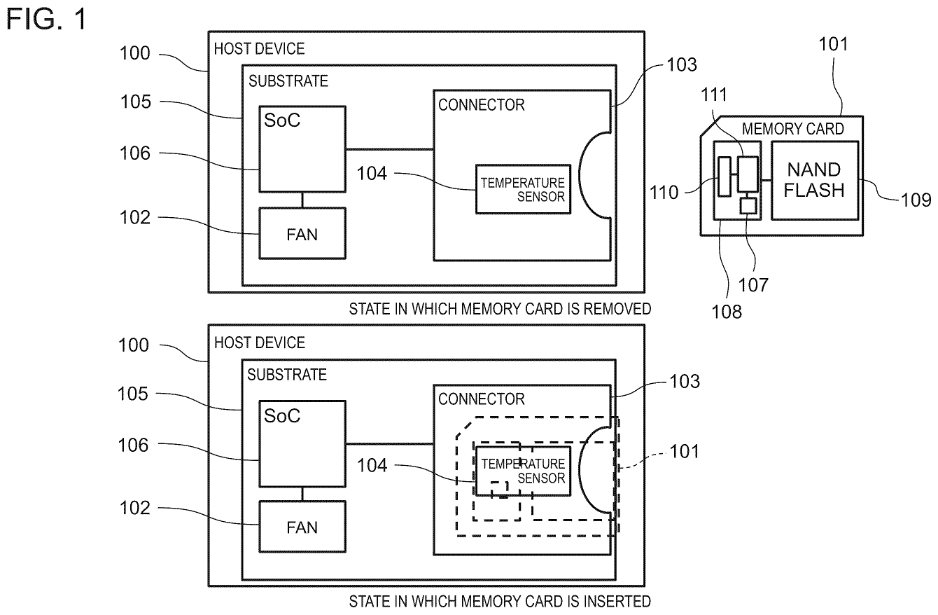

A first exemplary embodiment will be described below with reference to FIGS. 1 to 3, 7, and 8.

### [1-1. Configuration]

FIG. 1 is a schematic diagram illustrating a memory card and a connector mounted on a substrate of a host device according to the first exemplary embodiment.

Description will be made based on a diagram of a state in which memory card 101 described in an upper part of FIG. 1 is removed.

Substrate 105 of host device 100 is mounted with connector 103 into which memory card 101 can be inserted and removed. Connector 103 includes temperature sensor 104. Temperature sensor 104 is designed and disposed so as to be able to measure the surface temperature (case temperature) of memory card 101. In addition, a control unit capable of transmitting and receiving an electric signal is mounted on substrate 105. System on chip (SoC) 106 is an example of the control unit. SoC 106 is connected to connector 103 by signal line, and can transmit an electric signal from SoC 106 to connector 103. Furthermore, temperature information measured by temperature sensor 104 provided in connector 103 is notified to SoC 106 via a signal line. Furthermore, SoC 106 is connected to fan 102 by a signal line, and can transmit an electric signal from SoC 106 to fan 102. Fan 102 changes ON/OFF of operation, a rotation speed, and the like according to an electric signal from SoC 106.

Usually, host device 100 requires a dynamic random access memory (DRAM), other peripheral components, and the like, but these are not directly related to the contents of the present disclosure and are omitted.

Memory card 101 incorporates controller 108 and NAND FLASH 109 which is a nonvolatile memory as a memory. Controller 108 is connected to NAND FLASH 109. Controller 108 incorporates interface unit 110, control unit 111, and temperature sensor 107. Control unit 111 is connected to interface unit 110 and temperature sensor 107.

Interface unit 110 receives a command from SoC 106 and notifies control unit 111 of the command. Control unit 111 performs processing in response to the command, generates response information (setting information), and passes the response information to interface unit 110. Interface unit 110 returns the response information to SoC 106.

When interface unit 110 receives a write command (write command), control unit 111 writes write data received from SoC 106 to NAND FLASH 109 (write command processing). When interface unit 110 receives a read command (read command), control unit 111 reads data from NAND FLASH 109 and transmits the data to SoC 106 (read command processing). When interface unit 110 receives an erase command, control unit 111 erases the corresponding data based on the address included in the received command (erase command processing).

Control unit 111 can read a card internal temperature (an internal temperature of memory card 101) measured by temperature sensor 107. Temperature sensor 107 may be incorporated in NAND FLASH 109, or may be incorporated in memory card 101 as one component. In any implementation, control unit 111 can read a measurement result of temperature sensor 107.

FIG. 1 illustrates, in a lower part, a state in which memory card 101 is inserted into connector 103.

In a state where memory card 101 is inserted into connector 103 mounted on substrate 105 of host device 100, a command based on an electric signal from SoC 106 is received by memory card 101 via connector 103. Memory card 101 performs processing in response to the command, and returns response information. Memory card 101 performs write command processing, read command processing, erase command processing, and the like.

SoC 106 can acquire temperature information measured by temperature sensor 107 incorporated in memory card 101 as response information of a command from SoC 106 to memory card 101.

Temperature sensor 104 is installed at a position where a surface temperature of memory card 101 can be measured in a state where memory card 101 is inserted.

Temperature sensor 104 in FIG. 1 is drawn to measure the surface of memory card 101, but may be installed to measure the back surface side of memory card 101, or a plurality of temperature sensors may be installed to measure the surface temperature of memory card 101.

Memory card 101 has a minimum speed guarantee function. This function is a function of guaranteeing the write/read operation at the guaranteed speed or higher when host device 100 accesses memory card 101 according to a certain procedure. This guaranteed speed is a value unique to memory card 101, and SoC 106 can acquire the guaranteed speed as response information to a command from SoC 106 to memory card 101.

Memory card 101 has a thermal throttling function. This function is a function of performing function restriction and suppressing heat generation when a certain threshold temperature is exceeded. Memory card 101 can set a plurality of threshold temperatures at which thermal throttling is activated. For example, two threshold temperatures are defined as threshold temperatures TMT1 (Thermal Management Temperature 1) and TMT2 (Thermal Management Temperature 2), and threshold temperature TMT1 sets a threshold temperature smaller than threshold temperature TMT2 (TMT1<TMT2).

The outline of the operation of the thermal throttling function will be described. Control unit 111 acquires a card internal temperature from temperature sensor 107. Control unit 111 compares the acquired card internal temperature with each of threshold temperatures TMT1 and TMT2. When the card internal temperature does not exceed threshold temperature TMT1, control unit 111 does not activate thermal throttling. When the card internal temperature exceeds threshold temperature TMT1, control unit 111 activates thermal throttling (weak thermal throttling) by means such as lowering an internal operation clock. Further, when the card internal temperature exceeds threshold temperature TMT2, control unit 111 activates thermal throttling (strong thermal throttling) by means such as further lowering the internal operation clock.

Memory card 101 holds a maximum thermal management temperature (MXTMT) indicating a maximum value that can be set to threshold temperature TMT1 and threshold temperature TMT2. Maximum value MXTMT is a value unique to memory card 101, and SoC 106 can acquire the maximum value as response information of a command from SoC 106 to memory card 101.

For details of the thermal throttling function, threshold temperatures TMT1 and TMT2, and maximum value MXTMT, refer to the NVMe standard (NVM Express Revision 1.3 May 1, 2017).

### [1-2. Operation]

Operations of host device 100 and memory card 101 configured as described above will be described below. Host device 100 performs an operation of acquiring and setting a rising temperature or acquiring and setting a threshold temperature. Hereinafter, each of the operations is described in detail.

### [1-2-1. Acquiring and Setting of Rising Temperature]

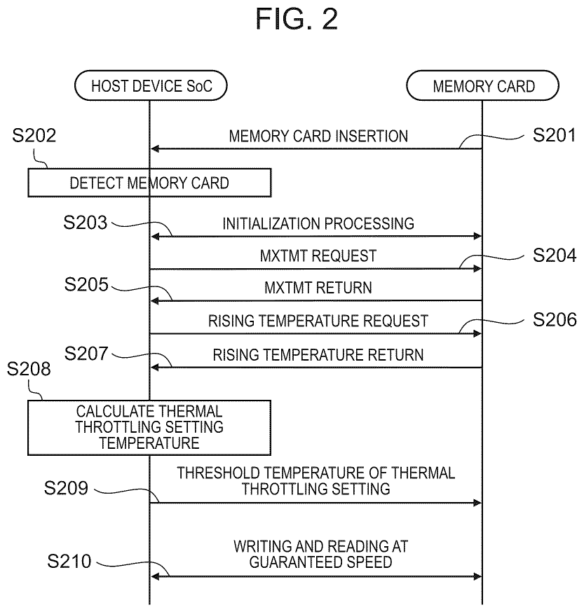

FIG. 2 is a sequence diagram for explaining operations of host device 100 and memory card 101 inserted into connector 103 of substrate 105 of host device 100. This is an example in which the threshold temperature is calculated on the host side.

Memory card 101 is inserted into connector 103 of substrate 105 of host device 100. Connector 103 is connected to SoC 106 mounted on host device 100 via a signal line. This information that memory card 101 has been inserted via a signal line is notified to SoC 106 (S201). SoC 106 detects insertion of memory card 101 (S202). SoC 106 transmits a command to memory card 101. Memory card 101 analyzes the received command and returns appropriate response information. Such a command and response information are repeated a plurality of times to execute initialization processing (S203). After the initialization processing, memory card 101 is brought into a state where writing, reading, erasing, and the like of data can be executed.

SoC 106 inquires of memory card 101 about card-specific maximum value MXTMT (S204). Memory card 101 returns card-specific maximum value MXTMT (S205).

Next, SoC 106 inquires of memory card 101 how many degrees the card internal temperature rises from the surface temperature of the memory card when memory card 101 continuously operates at the guaranteed speed unique to the card (S206). Memory card 101 returns response information including a rising temperature in the case of continuous operation at the guaranteed speed unique to the card (S207). That is, the rising temperature is a difference between the card surface temperature and the card internal temperature when the card is continuously operated at the guaranteed speed.

SoC 106 calculates a threshold temperature of thermal throttling from the rising temperature included in the response information and the convergence temperature (the surface temperature of memory card 101 reached as a result of control by host device 100 during continuous operation) (S208). SoC 106 transmits a command including the calculated threshold temperature to memory card 101 (S209). Memory card 101 sets the value included in the command to the threshold temperature (threshold temperature TMT1) of the thermal throttling. SoC 106 writes to and reads from the memory card at the guaranteed speed (S210).

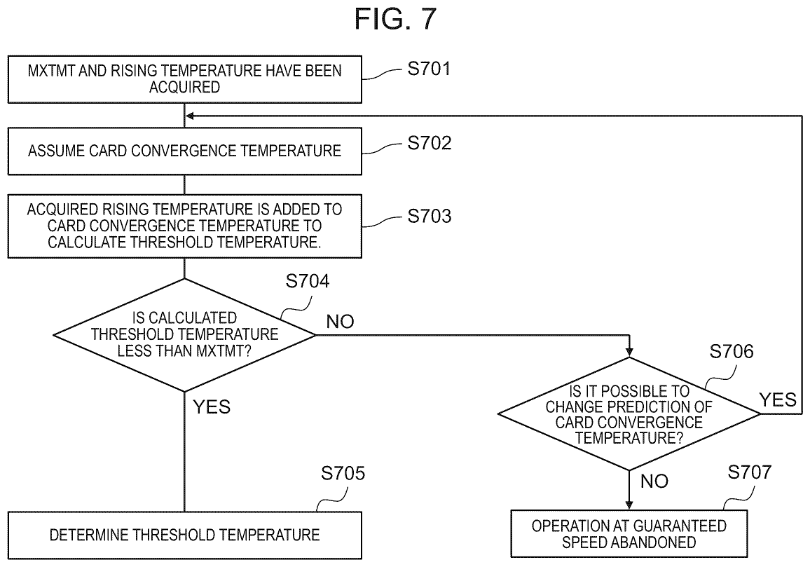

Calculation of the threshold temperature of the thermal throttling (S208) will be described with reference to FIG. 7. SoC 106 has already acquired maximum value MXTMT and the rising temperature (S701). SoC 106 assumes a convergence temperature of memory card 101 (S702). SoC 106 adds the acquired rising temperature to the assumed convergence temperature and further adds a positive margin to calculate a threshold temperature (S703). SoC 106 determines whether the threshold temperature calculated in step S703 is less than already acquired maximum value MXTMT (S704). When the threshold temperature is less than already acquired maximum value MXTMT, SoC 106 sets the calculated threshold temperature as the threshold temperature to be set in memory card 101. (S705). If the threshold temperature is not less than acquired maximum value MXTMT, SoC 106 determines whether the assumption of the card convergence temperature can be changed (S706). For example, SoC 106 may determine whether or not the rotation speed of fan 102 mounted on host device 100 can be increased. If the assumption of the card convergence temperature can be changed, SoC 106 assumes the card convergence temperature again (S702). If the assumption of the card convergence temperature cannot be changed, SoC 106 abandons the operation at the guaranteed speed (S707).

Note that the command to inquire about the rising temperature transmitted by SoC 106 may include the guaranteed speed to be operated. In this case, memory card 101 returns response information including a rising temperature when memory card 101 continuously operates at the guaranteed speed included in the received command. In addition, when the threshold temperature calculated from the rising temperature and the convergence temperature included in the response information is not less than maximum value MXTMT and the convergence temperature of the card cannot be changed, SoC 106 may change the guaranteed speed to be operated.

When the card internal temperature exceeds threshold temperature TMT1 and the guaranteed speed can be maintained even if the weak thermal throttling is activated, that is, when the access speed when the weak thermal throttling is activated can secure the guaranteed speed, memory card 101 may return response information to the effect that threshold temperature TMT2 may be set as response information of a command inquiring about the temperature rise value. In addition, memory card 101 may be configured such that information indicating whether threshold temperature TMT2 may be set can be separately acquired by a command, and SoC 106 may separately acquire the information by a command.

When host device 100 knows that the guaranteed speed can be maintained even if the card internal temperature exceeds threshold temperature TMT1 and weak thermal throttling is activated, the threshold temperature calculated using the temperature rise value obtained from memory card 101 may be set to threshold temperature TMT2.

Note that, instead of the inquiry about the rising temperature from SoC 106, the rising temperature may be returned by using another inquiry (inquiry about the guaranteed speed) as a trigger.

Furthermore, there is no inquiry from SoC 106, and the rising temperature may be sent spontaneously.

### [1-2-2. Acquiring and Setting of Threshold Temperature]

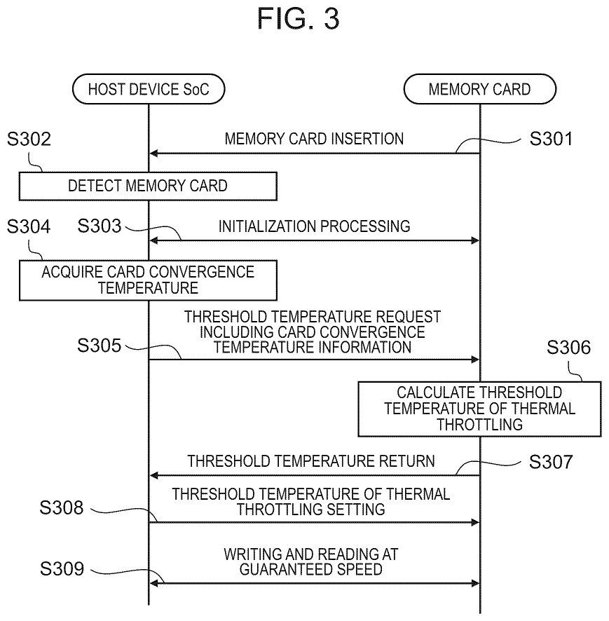

FIG. 3 is a sequence diagram for explaining operations of host device 100 and memory card 101 inserted into connector 103 of substrate 105. Although the threshold temperature is calculated on host device 100 side in FIG. 2, an example of calculation on the card side will be described in FIG. 3.

Memory card 101 is inserted into connector 103 of substrate 105 of host device 100. Connector 103 is connected to SoC 106 mounted on host device 100 via a signal line. This information that memory card 101 has been inserted via a signal line is notified to SoC 106 (S301).

SoC 106 detects insertion of memory card 101 (S302). SoC 106 transmits a command to memory card 101. Memory card 101 analyzes the received command and returns appropriate response information. Such a command and response information are repeated a plurality of times to execute initialization processing (S303). After the initialization processing, memory card 101 is brought into a state where writing, reading, erasing, and the like of data can be executed.

SoC 106 assumes a convergence temperature (S304). SoC 106 transmits a command including the convergence temperature to memory card 101. When memory card 101 is operated at a guaranteed speed unique to the card by this command, it is inquired to what degrees the threshold temperature of the thermal throttling should be set (S305).

Memory card 101 adds the rising temperature when operating at the guaranteed speed unique to the card to the convergence temperature, and calculates the threshold temperature of the thermal throttling to which a plus margin is further added (S306).

Memory card 101 returns response information including the calculated threshold temperature of the thermal throttling (S307).

SoC 106 transmits a command including the threshold temperature to memory card 101 (S308). Memory card 101 sets the threshold temperature included in the command as the threshold temperature of the thermal throttling.

SoC 106 performs writing and reading on memory card 101 at the speed of a speed guarantee value (S309).

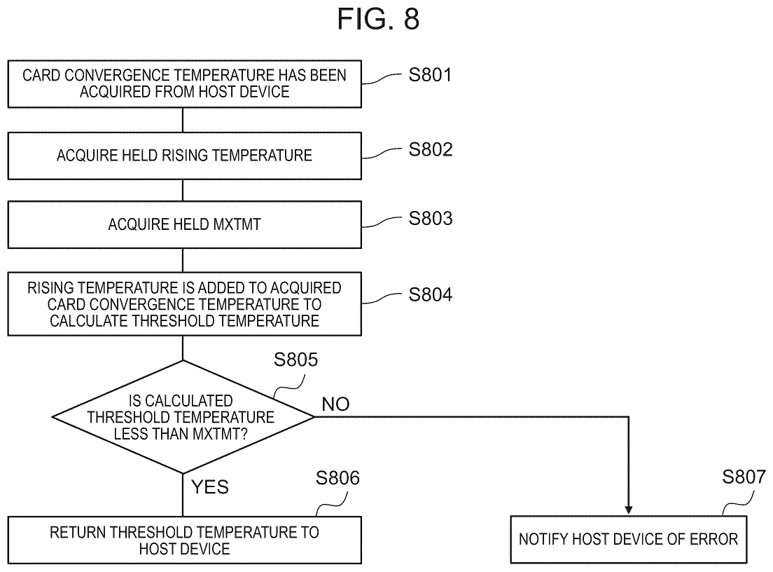

Calculation of the threshold temperature of the thermal throttling (S306) will be described with reference to FIG. 8. Memory card 101 has already acquired the convergence temperature from host device 100 (S801). Memory card 101 takes out the rising temperature when operating at the guaranteed speed unique to the card (S802). Memory card 101 takes out card-specific maximum value MXTMT (S803). Memory card 101 adds the rising temperature to the convergence temperature, and further adds a positive margin to calculate a threshold temperature (S804).

Memory card 101 determines whether the threshold temperature is less than maximum value MXTMT as the corresponding temperature (S805). When the threshold temperature is less than maximum value MXTMT, memory card 101 determines the threshold temperature calculated in step S804 as the threshold temperature of the thermal throttling, and returns the threshold temperature to host device 100 (S806). When the threshold temperature is not less than maximum value MXTMT, memory card 101 transmits an error notification indicating that the threshold temperature of the thermal throttling cannot be calculated to host device 100 (S807).

Note that the guaranteed speed information to be operated may be included in the command inquiring the threshold temperature of the thermal throttling transmitted by SoC 106. In this case, memory card 101 returns response information including the threshold temperature of the thermal throttling when SoC 106 operates at the guaranteed speed included in the command. In addition, when an error indicating that the threshold temperature of the thermal throttling cannot be calculated is received from memory card 101, SoC 106 may change the guaranteed speed to be operated and inquire the threshold temperature of the thermal throttling again.

When the card internal temperature exceeds threshold temperature TMT1 and the guaranteed speed can be maintained even if weak thermal throttling is activated, that is, when the access speed when weak thermal throttling is activated can secure the guaranteed speed, memory card 101 may return response information to the effect that threshold temperature TMT2 may be set as response information of a command inquiring about the threshold temperature of the thermal throttling. In addition, memory card 101 may be configured such that information indicating whether threshold temperature TMT2 may be set can be separately acquired by a command, and SoC 106 may separately acquire the information by a command.

When host device 100 knows that the guaranteed speed can be maintained even if the card internal temperature exceeds threshold temperature TMT1 and weak thermal throttling is activated, the threshold temperature of the thermal throttling obtained from memory card 101 may be set to threshold temperature TMT2.

Memory card 101 may include a plurality of threshold temperatures of the thermal throttling in the response information as designation information. The plurality of threshold temperatures are included in the response information according to a rule determined in advance, and SoC 106 recognizes the threshold temperature according to the rule. The recognized threshold temperature is set as the threshold temperature of the thermal throttling of memory card 101.

For example, when the card internal temperature of memory card 101 exceeds threshold temperature TMT1 and the guaranteed speed can be maintained even if weak thermal throttling is activated, that is, when the access speed when weak thermal throttling is activated can secure the guaranteed speed, the calculated threshold temperature of the thermal throttling is set as threshold temperature TMT2 and a value lower than threshold temperature TMT2 is set as threshold temperature TMT1. These two threshold temperatures of the thermal throttling are included in the response information in a predetermined order and returned. SoC 106 recognizes the threshold temperatures of threshold temperatures TMT1 and TMT2 according to the order, and sets the threshold temperatures in memory card 101 as threshold temperatures of the thermal throttling.

Note that a rule may be adopted in which the lower thermal throttling set value is threshold temperature TMT1 and the higher thermal throttling set value is threshold temperature TMT2.

Note that the threshold temperature may be returned by using another inquiry (inquiry of the guaranteed speed) as a trigger instead of the inquiry of the threshold temperature from SoC 106.

In addition, the threshold temperature may be voluntarily sent without an inquiry from SoC 106.

### [1-3. Effects and the Like]

As described above, in the first exemplary embodiment, SoC 106 of host device 100 issues, to inserted memory card 101, a command for requesting a rising temperature when memory card 101 is continuously operated at a guaranteed speed unique to the card. Memory card 101 returns response information including a rising temperature to SoC 106. As a result, SoC 106 of host device 100 calculates the threshold temperature of the thermal throttling from the temperature rise and the convergence temperature in the case of continuous operation at the guaranteed speed unique to the card. As a result, the threshold temperature of the thermal throttling can be appropriately set. Therefore, excessive thermal throttling does not occur, and writing and reading can be performed at a guaranteed speed.

In the first exemplary embodiment, SoC 106 of host device 100 issues a command including an assumed convergence temperature to inserted memory card 101. Memory card 101 calculates the threshold temperature of the thermal throttling obtained by adding an assumed convergence temperature and a rising temperature. Memory card 101 returns response information including the calculated value. SoC 106 sets the returned threshold temperature in memory card 101. As a result, the threshold temperature of the thermal throttling can be appropriately set. Therefore, excessive thermal throttling does not occur, and writing and reading can be performed at a guaranteed speed.

### Second Exemplary Embodiment

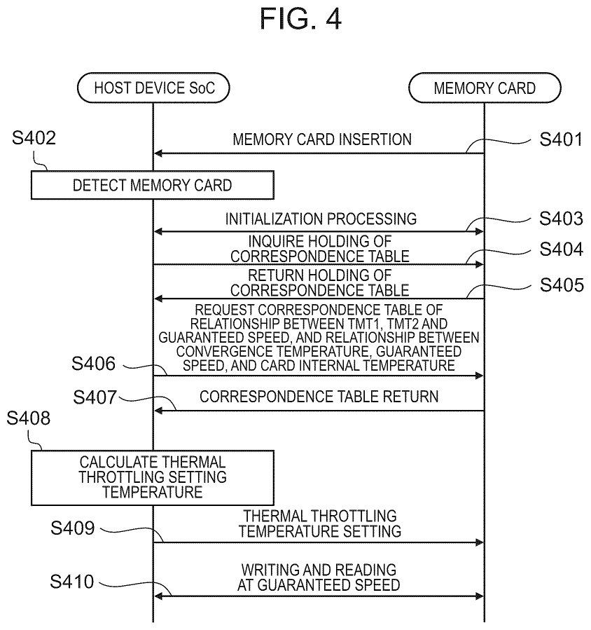

Hereinafter, a second exemplary embodiment will be described with reference to FIGS. 4 to 6, 9, and 10. In the second exemplary embodiment, an example will be described in which host device 100 acquires the relationship between threshold temperatures TMT1, TMT2, which are card-specific thresholds at which the thermal throttling becomes activate, and the guaranteed speed, and the relationship between the convergence temperature, the guaranteed speed, and the card internal temperature, calculates the threshold temperature, and further controls a cooling function of host device 100.

### [2-1. Configuration]

Since it is the same as the first exemplary embodiment, it is omitted.

### [2-2. Operation]

Operations of host device 100 and memory card 101 configured as described above will be described below.

FIG. 4 is a sequence diagram for explaining operations of host device 100 and memory card 101 inserted into connector 103 of substrate 105 of host device 100.

Memory card 101 is inserted into connector 103 of substrate 105 of host device 100. Connector 103 is connected to SoC 106 mounted on host device 100 via a signal line. This information that memory card 101 has been inserted via a signal line is notified to SoC 106 (S401).

SoC 106 detects insertion of memory card 101 (S402). SoC 106 transmits a command to memory card 101. Memory card 101 analyzes the received command and returns appropriate response information. Such a command and response information are repeated a plurality of times to execute initialization processing (S403). After the initialization processing, memory card 101 is brought into a state where writing, reading, erasing, and the like of data can be executed.

SoC 106 inquires of memory card 101 whether a correspondence table of the relationship between threshold temperatures TMT1, TMT2 and the guaranteed speed, and the relationship between the convergence temperature, the guaranteed speed, and the card internal temperature is held (S404). Memory card 101 returns response information indicating that the correspondence table is held (S405). SoC 106 requests a correspondence table of the relationship between threshold temperatures TMT1, TMT2 and the guaranteed speed, and the relationship between the convergence temperature, the guaranteed speed, and the card internal temperature (S406). Memory card 101 returns the correspondence table (S407).

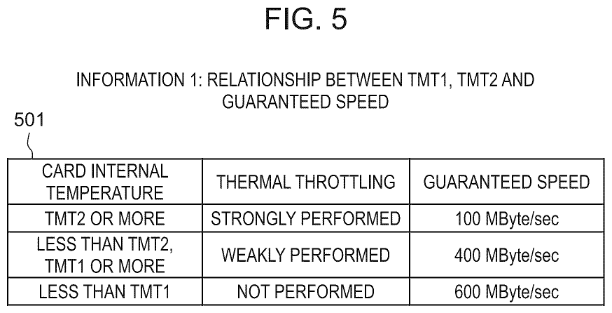

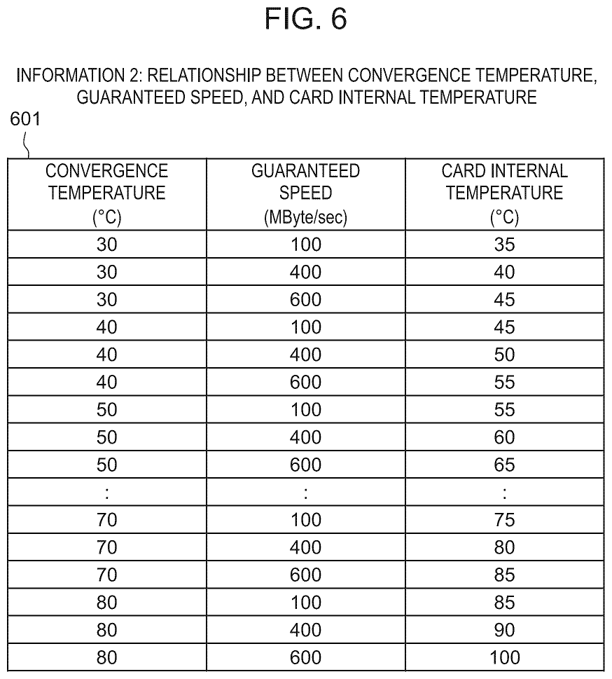

Here, examples of the correspondence table are illustrated in FIGS. 5 and 6. FIG. 5 is an example illustrating a relationship between threshold temperatures TMT1, TMT2, which are thresholds at the thermal throttling becomes activate, and the guaranteed speed, and this information is held in memory card 101.

The card internal temperature in correspondence table 501 is a temperature measured by temperature sensor 107 built in memory card 101. What is meant by correspondence table 501 is as follows.

When the card internal temperature is equal to or higher than threshold temperature TMT2, memory card 101 strongly performs thermal throttling. Therefore, it is indicated that the guaranteed speed is 100 Mbyte/sec. Similarly, when the card internal temperature is less than threshold temperature TMT2 and equal to or higher than threshold temperature TMT1, memory card 101 weakly performs thermal throttling. Therefore, it is indicated that the guaranteed speed is 400 Mbyte/sec. When the card internal temperature is less than threshold temperature TMT1, it is indicated that memory card 101 does not perform thermal throttling, and thus the guaranteed speed is 600 Mbyte/sec.

The content indicated by correspondence table 501 also has the following meanings.

The guaranteed speed of 100 Mbyte/sec can be realized even when the card internal temperature at the time of continuous operation at the guaranteed speed is equal to or higher than threshold temperature TMT2. Therefore, the threshold setting of threshold temperatures TMT2, TMT1 is arbitrary.

In order to realize the guaranteed speed of 400 Mbyte/sec, the card internal temperature at the time of continuous operation at the guaranteed speed needs to be lower than threshold temperature TMT2. That is, threshold temperature TMT2 needs to be a threshold temperature larger than the card internal temperature at the time of continuous operation at the guaranteed speed. Threshold temperature TMT1 may be a value smaller than threshold temperature TMT2 (TMT1<TMT2).

In order to realize the guaranteed speed of 600 Mbyte/sec, the card internal temperature at the time of continuous operation at the guaranteed speed needs to be lower than threshold temperature TMT1. That is, threshold temperature TMT1 needs to be a threshold temperature larger than the card internal temperature at the time of continuous operation at the guaranteed speed. Threshold temperature TMT2 may be a value larger than threshold temperature TMT1.

FIG. 6 is an example showing the relationship between the convergence temperature, the guaranteed speed, and the card internal temperature, and this information is held in memory card 101. The convergence temperature is a surface temperature of memory card 101 that reaches as a result of control by host device 100 during continuous operation. What is meant by correspondence table 601 is as follows.

Correspondence table 601 indicates to what ° C. the card internal temperature rises when a certain convergence temperature is maintained and the card is continuously operated at a guaranteed speed. Specifically, it indicates that when the convergence temperature is 30° C., the card internal temperature becomes 35° C. when memory card 101 is continuously operated at the guaranteed speed of 100 Mbyte/sec. In addition, when the convergence temperature is 30° C., it indicates that the card internal temperature is 40° C. when memory card 101 is continuously operated at the guaranteed speed of 400 Mbyte/sec, and the card internal temperature is 45° C. when memory card 101 is continuously operated at the guaranteed speed of 600 Mbyte/sec. The same applies to other convergence temperatures.

The content indicated by correspondence table 601 also has the following meanings.

In a case where a continuous operation is performed at a certain guaranteed speed and the card internal temperature is desired to be set to a certain temperature, it is indicated to what degrees the convergence temperature should be set. Specifically, in a case where the continuous operation is performed at a guaranteed speed of 100 Mbyte/sec and the card internal temperature is desired to be set up to 35° C., it is indicated that the convergence temperature needs to be set to 30° C. In addition, in a case where the continuous operation is performed at a guaranteed speed of 100 Mbyte/sec and the card internal temperature is desired to be set up to 45° C., it is indicated that the convergence temperature needs to be set to 40° C., and in a case where the card internal temperature is desired to be set up to 55° C., it is indicated that the convergence temperature needs to be set to 50° C. The same applies to other guaranteed speeds and other card internal temperatures.

The content indicated by correspondence table 601 also has the following meanings.

In a case where it is desired to maintain the card internal temperature to a certain temperature and the convergence temperature can be maintained at a certain temperature, it is indicated that the operation can be performed at a guaranteed speed of what Mbyte/sec. Specifically, in a case where it is desired to maintain the card internal temperature up to 85° C. and the convergence temperature can be maintained at 80° C., it indicates that the operation can be performed at the guaranteed speed of 100 Mbyte/sec. In a case where it is desired to maintain the card internal temperature up to 85° C. and the convergence temperature can be maintained at 70° C., it indicates that the operation can be performed at the guaranteed speed of 600 Mbyte/sec. In a case where it is desired to maintain the card internal temperature up to 80° C. and the convergence temperature can be maintained at 70° C., it indicates that the operation can be performed at the guaranteed speed of 400 Mbyte/sec. The same applies to other card internal temperatures and other convergence temperatures.

The description of FIG. 4 will be continued. SoC 106 calculates the threshold temperature of the thermal throttling based on the returned correspondence tables of FIGS. 5 and 6 (S408). For example, it is assumed that SoC 106 wants to access memory card 101 at 400 Mbyte/sec.

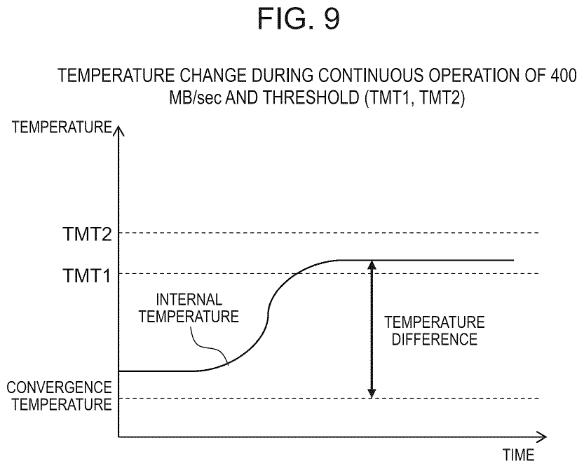

Here, a change in the card internal temperature will be supplemented with reference to FIG. 9. FIG. 9 is an example illustrating a change in the card internal temperature and a threshold at the time of 400 Mbyte/sec continuous operation. As illustrated in FIG. 9, the card internal temperature rises when the card is operated, and reaches a certain temperature. The difference between the reached card internal temperature and the convergence temperature is a temperature difference. From the correspondence table of FIG. 5, when the card internal temperature is less than threshold temperature TMT2 and is equal to or higher than threshold temperature TMT1, the guaranteed speed is 400 Mbyte/sec, and when the card internal temperature is less than threshold temperature TMT1, the guaranteed speed is 600 Mbyte/sec. That is, the guaranteed speed of 400 Mbyte/sec can be realized by setting threshold temperature TMT2 higher than the reached card internal temperature. Assuming that host device 100 can be cooled so that the convergence temperature becomes 40° C., it can be seen from correspondence table 601 that the card internal temperature becomes 50° C. From these, it can be seen that threshold temperature TMT2 needs to be set to a value higher than 50° C. SoC 106 adds a positive margin, for example, 5° C. to 50° C. to calculate 55° C. as the threshold temperature.

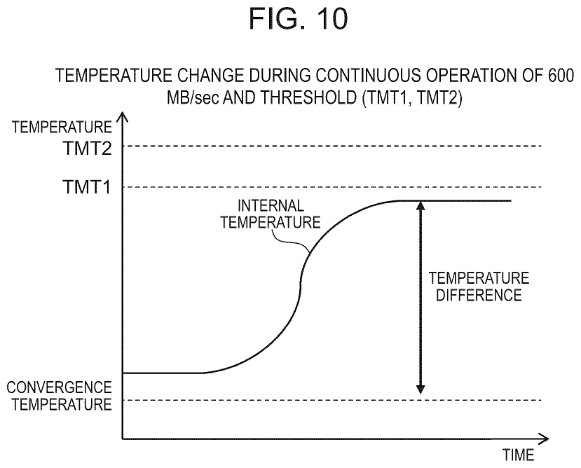

For example, it is assumed that SoC 106 wants to access memory card 101 at 600 Mbyte/sec. Here, a change in the card internal temperature will be supplemented with reference to FIG. 10. FIG. 10 is an example illustrating a change in the card internal temperature and the threshold at the time of continuous operation of 600 Mbyte/sec. As illustrated in FIG. 10, the card internal temperature rises when the card is operated, and reaches a certain temperature. If the other conditions are the same, the reached temperature is higher than the temperature reached during the continuous operation of 400 Mbyte/sec. The difference between the reached card internal temperature and the convergence temperature is a temperature difference. From the correspondence table of FIG. 5, when the card internal temperature is lower than threshold temperature TMT1, the guaranteed speed is 600 Mbyte/sec. That is, the guaranteed speed of 600 Mbyte/sec can be realized by setting threshold temperature TMT1 higher than the reached card internal temperature. Assuming that host device 100 can be cooled so that the convergence temperature becomes 40° C., it can be seen from correspondence table 601 that the card internal temperature becomes 55° C. From these, it can be seen that threshold temperature TMT1 needs to be set to a value higher than 55° C. SoC 106 adds a positive margin, for example, 5° C. to 55° C. to calculate 60° C. as the threshold temperature.

SoC 106 transmits, to memory card 101, a command including the threshold temperature and selection information indicating to which of threshold temperatures TMT1, TMT2 of the thermal throttling the threshold temperature is set (S409). Memory card 101 sets the threshold temperature calculated for the thermal throttling threshold selected according to the selection information as the threshold temperature of the thermal throttling. SoC 106 writes and reads to and from memory card 101 at the speed guarantee value (S410).

A convergence temperature for realizing a certain guaranteed speed may be calculated from the acquired correspondence tables of FIGS. 5 and 6. For example, it is assumed that host device 100 accesses at the guaranteed speed of 600 Mbyte/sec, and the value of maximum value MXTMT separately acquired is 95° C. In this case, it can be seen from correspondence table 601 that when the convergence temperature is 80° C. and the guaranteed speed is 600 Mbyte/sec, the card internal temperature becomes 100° C. and exceeds maximum value MXTMT. On the other hand, when the convergence temperature is 70° C. and the guaranteed speed is 600 Mbyte/sec, the card internal temperature is 90° C. and is equal to or less than maximum value MXTMT. From this, host device 100 can calculate that the convergence temperature needs to be set to 70° C. or lower. The host device can operate an appropriate cooling function, such as operating fan 102 such that the card surface temperature is 70° C. or less.

Note that, host device 100 may assume the convergence temperature from the capability of cooling the surface temperature of memory card 101, and may calculate the guaranteed speed from the card internal temperature obtained from acquired correspondence table 601 and maximum value MXTMT that can be separately acquired. For example, it is assumed that host device 100 assumes a convergence temperature of memory card 101 as 80° C., and a value of maximum value MXTMT separately acquired is 95° C. In this case, it can be seen from correspondence table 601 that when the convergence temperature is 80° C. and the guaranteed speed is 600 Mbyte/sec, the card internal temperature is 100° C. The card internal temperature is higher than 95° C. which is maximum value MXTMT. Therefore, it can be seen that the operation at the guaranteed speed of 600 Mbyte/sec is impossible at the card surface temperature of 80° C. On the other hand, when the guaranteed speed is 400 Mbyte/sec, the card internal temperature increases only up to 90° C. From this, when the convergence temperature is 80° C., it can be calculated that the operation can be performed at the guaranteed speed of 400 Mbyte/sec.

Note that the card internal temperature in correspondence table 601 is not a specific temperature but may be a value indicating that the temperature cannot be set when the card internal temperature exceeds maximum value MXTMT.

Note that SoC 106 may access memory card 101 at a speed equal to or lower than the guaranteed speed.

Note that SoC 106 may calculate a plurality of thresholds and transmit commands including the thresholds in a predetermined order.

The guaranteed speed is an example, and other numerical values may be used.

The temperature difference with respect to each guaranteed speed value may be individually acquired from the card.

Although one speed guarantee value corresponds to one thermal throttling operation in the example of the present exemplary embodiment, a plurality of speed guarantee values may correspond to one thermal throttling operation.

Note that the correspondence table may be returned by using another request (request for the guaranteed speed) instead of the request of the correspondence table from SoC 106 as a trigger.

In addition, the correspondence table may be voluntarily sent without the request of the correspondence table from SoC 106.

### [2-3. Effects, etc.]

As described above, in the second exemplary embodiment, SoC 106 of host device 100 issues a command to inserted memory card 101 to check whether the correspondence table of the relationship between threshold temperatures TMT1, TMT2 and the guaranteed speed, and the relationship between the convergence temperature, the guaranteed speed, and the card internal temperature is held. Memory card 101 returns response information including whether the correspondence table is held to SoC 106. After confirming that memory card 101 holds the correspondence table by the response information, SoC 106 issues, to memory card 101, a command for requesting a correspondence table of a relationship between threshold temperatures TMT1, TMT2 and a guaranteed speed, and a relationship between a convergence temperature, a guaranteed speed, and a card internal temperature. Memory card 101 returns response information including the correspondence table.

Using the acquired correspondence table, SoC 106 of host device 100 calculates a threshold temperature of thermal throttling in a case where host device 100 accesses memory card 101 at a desired guaranteed speed assuming a convergence temperature. As a result, the thermal throttling setting value can be appropriately set. Therefore, excessive thermal throttling does not occur, and writing and reading can be performed at a guaranteed speed.

### Other Exemplary Embodiments

First to second exemplary embodiments have been described above as an example of the technique disclosed in the present application. However, the technique of the present disclosure is not limited thereto, and can also be applied to exemplary embodiments subjected to alteration, substitution, addition, omission, and the like. Further, a new exemplary embodiment can be made by combining components described in the above first to second exemplary embodiments.

In the first and second exemplary embodiments, memory card 101 is used as an example of the recording medium. The recording medium may be any recording medium capable of writing and reading data. Therefore, the recording medium is not limited to memory card 101. However, when memory card 101 is used, handling is easy. In addition, a recording medium having a shape of M.2 or U.2 may be used. When a recording medium having a shape of M.2 or U.2 is used, the recording capacity is easily increased. Furthermore, the recording medium may be a recording medium incorporated in a device. When the built-in recording medium is used, heat is easily released to the substrate of the host device.

In the first and second exemplary embodiments, NAND FLASH 109 is used as an example of the nonvolatile memory. The nonvolatile memory may hold data even in a state where power is not supplied. However, when NAND FLASH is used as the nonvolatile memory, the nonvolatile memory can be obtained at low cost.

In the first and second exemplary embodiments, fan 102 is used as an example of the cooling component. The cooling component may be any component that can cool the recording medium. However, when a fan is used as the cooling component, the cooling component can be obtained at low cost. A component including a Peltier element may be used as the cooling component. When the component including the Peltier element is used, there is an effect that the operating sound becomes quieter. As the cooling component, a water-cooling type cooling device may be used. When the water-cooling type cooling device is used, cooling can be performed with high efficiency.

Note that, since the above-described exemplary embodiments are intended to illustrate the technique in the present disclosure, various changes, replacements, additions, omissions, and the like can be made within the scope of the claims and equivalents thereof.

The present disclosure is applicable to a device that writes and reads data while generating heat at a high temperature. Specifically, the present disclosure is applicable to a digital camera, a movie camera, a smartphone, a drone, a personal computer, and the like.

What is claimed is:

1. A recording medium connected to a host device, the recording medium comprising:
a memory;
a control unit that controls the memory; and
an interface unit that communicates with the host device, wherein
the interface unit
transmits setting information including a rising temperature that is a temperature difference between a surface and an inside of the recording medium, and
receives a threshold temperature of thermal throttling from the host device, and
the control unit
controls an operation based on the threshold temperature.

2. The recording medium according to claim 1, wherein the setting information is transmitted after an initialization command is received from the host device and initialization processing is completed.

3. The recording medium according to claim 1, wherein the rising temperature is the temperature difference reached when the memory continues to operate at a guaranteed speed held by the memory.

4. The recording medium according to claim 1, wherein
the interface unit transmits the setting information after receiving command information inquiring about the rising temperature from the host device, and
in a case where a guaranteed speed desired by the host device is included in the command information, the rising temperature is the temperature difference reached when the operation is continued at the guaranteed speed.

5. The recording medium according to claim 1, wherein the setting information includes designation information indicating to which thermal throttling threshold among a plurality of thermal throttling thresholds held by the memory the setting information is set.

6. A host device connected to a recording medium, the host device comprising a control unit, wherein the control unit
receives setting information including a rising temperature that is a temperature difference between a surface and an inside of the recording medium,
calculates a threshold temperature based on the setting information and a convergence temperature that is a surface temperature of the recording medium that can be controlled when the recording medium is continuously operated at a guaranteed speed, and
transmits the threshold temperature calculated to the recording medium.

7. A recording medium connected to a host device, the recording medium comprising:
a memory;
a control unit that controls the memory; and
an interface unit that communicates with the host device, wherein
the interface unit
receives command information including a convergence temperature that is a temperature that can be controlled when the host device is continuously operated,
transmits setting information including a threshold temperature calculated by the control unit based on the convergence temperature and a rising temperature that is a temperature difference between a surface and an inside of the recording medium, and
receives a threshold temperature of thermal throttling from the host device, and
the control unit
controls an operation based on the threshold temperature of the thermal throttling.

8. The recording medium according to claim 7, wherein the setting information is transmitted after an initialization command is received from the host device and initialization processing is completed.

9. The recording medium according to claim 7, wherein the rising temperature is the temperature difference reached when the memory continues to operate at a guaranteed speed held by the memory.

10. The recording medium according to claim 7, wherein in a case where a guaranteed speed desired by the host device is included in the command information, the rising temperature is the temperature difference reached when the operation is continued at the guaranteed speed.

11. The recording medium according to claim 7, wherein when the threshold temperature calculated exceeds a corresponding temperature, a fact is returned as the setting information to the host device.

12. The recording medium according to claim 7, wherein the setting information includes, in addition to the threshold temperature calculated, designation information indicating to which thermal throttling threshold among a plurality of thermal throttling thresholds held by the memory the setting information is set.

13. The recording medium according to claim 7, wherein
the control unit calculates a plurality of threshold temperatures, and
the setting information includes the plurality of threshold temperatures.

14. A host device connected to a recording medium, the host device comprising a control unit, wherein the control unit
transmits, to the recording medium, command information including a convergence temperature that is a temperature that can be controlled when the recording medium is continuously operated,
receives setting information including a threshold temperature calculated by the recording medium based on the convergence temperature and a rising temperature that is a temperature difference between a surface and an inside of the recording medium, and
transmits the threshold temperature included in the setting information to the recording medium as a threshold temperature of thermal throttling.

15. The host device according to claim 14, wherein the host device
receives, with respect to the command information, the setting information including a plurality of threshold temperatures from the recording medium, and
transmits, to the recording medium, the plurality of threshold temperatures as a plurality of thermal throttling thresholds.

16. A recording medium connected to a host device, the recording medium comprising:
a memory;
a control unit that controls the memory; and
an interface unit that communicates with the host device, wherein
the interface unit
transmits setting information including a relationship between a thermal throttling threshold and a guaranteed speed, and a relationship between a convergence temperature, the guaranteed speed, and an internal temperature of the recording medium, and
receives a threshold temperature of thermal throttling from the host device, and
the control unit
controls an operation based on the threshold temperature.

17. The recording medium according to claim 16, wherein the setting information is transmitted after an initialization command is received from the host device and initialization processing is completed.

18. A host device connected to a recording medium, the host device comprising a control unit, wherein the control unit
receives setting information including a relationship between a thermal throttling threshold and a guaranteed speed held by the recording medium, and a relationship between a convergence temperature, the guaranteed speed, and an internal temperature of the recording medium,
calculates a threshold temperature of thermal throttling and selection information obtained by selecting one of a plurality of thermal throttling thresholds from the relationship between the thermal throttling threshold and the guaranteed speed and the relationship between the convergence temperature, the guaranteed speed, and the internal temperature of the recording medium, and
transmits the selection information and the threshold temperature to the recording medium.

19. The host device according to claim 18, wherein the control unit
calculates an internal temperature of the recording medium related to a desired guaranteed speed from the desired guaranteed speed and the relationship between the convergence temperature, the guaranteed speed and the internal temperature of the recording medium,
calculates the threshold temperature based on the internal temperature of the recording medium related to the desired guaranteed speed, and
calculates the selection information from a relationship between the desired guaranteed speed, the thermal throttling threshold, and the guaranteed speed.

20. The host device according to claim 18, wherein
the calculation of the threshold temperature includes calculating a convergence temperature related to a desired guaranteed speed from the desired guaranteed speed, a maximum temperature that can be set as the thermal throttling threshold, and the relationship between the convergence temperature, the guaranteed speed, and the internal temperature of the recording medium, and
the control unit operates a cooling function according to the convergence temperature related to the desired guaranteed speed.
